(19) United States
(12) Patent Application Publication
(10) Pub. No.: US 2026/0254412 A1
(43) Pub. Date: Aug. 27, 2026

(54) Transmitter for Millimetre Radio Wavelengths

(71) Applicant: Millibeam Holdings Pty Ltd, Eveleigh, New South Wales (AU)

(72) Inventor: Venkata Krishna Mohan GUTTA, Eveleigh (AU)

(73) Assignee: Millibeam Holdings Pty Ltd, Eveleigh, New South Wales (AU)

(21) Appl. No.: 19/161,661

(22) PCT Filed: Mar. 1, 2024
(86) PCT No.: PCT/AU2024/050168

§ 371 Date: Sep. 2, 2025

(30) Foreign Application Priority Data
Mar. 3, 2023 (AU) 2023900563

(51) Int. Cl. H03F 1/02; H03F 3/24; H03G 3/30

(52) U.S. Cl. CPC H03F 1/0288; H03F 3/245; H03G 3/3042; H03F 2200/451; H03G 2201/103; H03G 2201/307

(57) ABSTRACT

Disclosed is a transmitter for transmitting radio frequency and millimeter wavelength signals. The transmitter comprises a first and a second transmission path, each transmission path having a signal with a different phase. The transmitter also comprises a first driver amplifier on the first transmission path and a second driver amplifier on the second transmission path, each of the first and second driver amplifiers receiving an input signal mixed with a carrier signal. The also transmitter comprises a first Doherty power amplifier on the first transmission path and a second Doherty power amplifier on the second transmission path, each of the first and the second Doherty power amplifiers having an input with a different phase and being configured to operate separately, wherein first driver amplifier is paired with the first Doherty power amplifier and the second driver amplifier is paired with the second Doherty power amplifier.

### TECHNICAL FIELD

The present invention generally relates to radio frequency transmitters and more particularly to millimetre-wave radio transmitter.

### BACKGROUND

Mobile communication networks have undergone innovation to increase bandwidth and energy efficiency to meet growing consumer demand for telecommunications infrastructure. The latest generation of mobile communications falls under the fifth-generation (5G) standard with 5G New Radio (5G NR) being the radio access technology underpinning the 5G standard.

5G NR operates in two frequency ranges. The first includes 6 GHz frequencies and below. The second frequency range includes the millimetre wavelength (mmWave) frequencies, which operate at much higher frequencies of around 30 GHz and higher. Having a short range and high frequency, the mmWave spectrum is advantageous in crowded environments with a high number of connections, such as shopping centres, sports stadiums, or city centres. In these crowded environments, where previous technologies may have faltered, mm Wave frequencies can deliver high data rates to a large number of people.

Millimetre wavelength transmitters consume high amounts of energy. Existing millimetre wavelength transmitters utilise circuit architectures and components designed for lower frequency signals. This means that they may not be energy efficient, and that the transmitters may not be sufficiently linear and as a result transmit distorted signals.

Existing millimetre wavelength transmitters may utilise a Doherty power amplifier in their design to improve the average efficiency of the transmitter. These architectures are normal in high power base stations at frequencies under 6 GHz. However, their performance may be less suited to operation at millimetre wavelength frequencies.

The preferred embodiments of the present invention seek to address a at least one of these disadvantages, to provide the public with a useful innovation.

The reference in this specification to any prior publication (or information derived from the prior publication), or to any matter which is known, is not, and should not be taken as an acknowledgement or admission or any form of suggestion that the prior publication (or information derived from the prior publication) or known matter forms part of the common general knowledge in the field of endeavour to which this specification relates.

### SUMMARY

This Summary is provided to introduce a selection of concepts in a simplified form which will be elaborated upon below in the Detailed Description. This Summary is not intended to identify essential features of the claimed subject matter, nor is it intended to be used to limit the scope for the claimed subject matter.

Disclosed is a transmitter for transmitting radio frequency and millimetre wavelength signals, the transmitter comprising: a first and a second transmission path, each transmission path having a signal with a different phase; a first driver amplifier on the first transmission path and a second driver amplifier on the second transmission path, each of the first and second driver amplifiers receiving an input signal mixed with a carrier signal; and a first Doherty power amplifier on the first transmission path and a second Doherty power amplifier on the second transmission path, each of the first and the second Doherty power amplifiers having an input with a different phase and being configured to operate separately, wherein first driver amplifier is paired with the first Doherty power amplifier and the second driver amplifier is paired with the second Doherty power amplifier.

In one embodiment the transmitter further comprises: a first output impedance inverter for an output of the first Doherty power amplifier; and a second output impedance inverter for an output of the second Doherty power amplifier, the first output impedance inverter and the second output impedance inverter being positioned to act as coupled impedance inverters.

In one embodiment, the second Doherty power amplifier is selectively operated based on DC bias conditions and an amplitude split ratio between the first and the second transmission paths.

In one embodiment, the first Doherty power amplifier is a low power Doherty power amplifier that is active for all power ranges and the second Doherty power amplifier is a high power Doherty power amplifier that is inactive for lower power ranges and active for higher power ranges.

In one embodiment, the phase difference between the input to the first Doherty power amplifier and the second Doherty power amplifier is substantially 90 degrees.

In one embodiment at least one of the first and the second driver amplifiers has an adjustable gain.

In one embodiment, the adjustable gain of the at least one driver amplifier varies an amplitude split between the first and the second Doherty power amplifiers.

In one embodiment, the carrier signal is generated by an oscillator.

In one embodiment, the carrier signal is phase adjusted before being received as input to at least one of the first and the second Doherty power amplifiers.

In one embodiment, a phase of the carrier signal is adjusted using a phase shifter for each of the plurality of Doherty power amplifiers, the phase shifter and a driver amplifier selected from the set of the first driver amplifier and the second driver amplifier applying pre-distortion to the up-converted RF signal.

In one embodiment, an amount of pre-distortion applied to the up-converted RF signal is adjusted using a variable gain of the driver amplifier and a variable phase of the phase shifter.

In one embodiment, each of the first and the second Doherty power amplifiers has a phase compensator for a main amplifier and a phase compensator for a peak amplifier.

In one embodiment the transmitter frequency is between 0.5 to 6 GHz.

In one embodiment the transmitter frequency is between 20 to 100 GHz

In one embodiment, each of the first and second transmission paths have an adjustable phase.

In one embodiment, the transmitter further comprises an output phase shifter that ensures that the low power Doherty power amplifier is load-modulated by the high power Doherty power at higher powers of operation.

In one embodiment, the low power Doherty power amplifier amplifies an in-phase signal and the high power Doherty power amplifier amplifies a quadrature phase signal before the in-phase signal and the quadrature phase signal are combined.

In one embodiment, a mobile device comprises the transmitter.

Also disclosed is a method of transmitting radio frequency and millimetre wavelength signals, the method comprising: generating an in-phase signal and a quadrature phase signal from an input signal; combining the in-phase signal with a carrier signal to form a combined in-phase signal and the quadrature signal with a carrier signal to form a combined quadrature signal; amplifying the combined in-phase signal with a low power Doherty power amplifier to generate an amplified in-phase signal; amplifying the combined quadrature signal with a high power Doherty power amplifier to generate an amplified quadrature signal; generating an output signal by combining the amplified in-phase signal and the amplified quadrature signal after adjusting a phase of at least one of the amplified in-phase signal and the amplified quadrature signal; and transmitting the output signal.

In one embodiment each of the combined in-phase signal and the combined quadrature phase signal are amplified by a driver amplifier

### BRIEF DESCRIPTION OF FIGURES

FIG. 1 illustrates a radio frequency transmitter;

FIG. 2 illustrates efficiency of a Doherty amplifier and a class B amplifier;

FIG. 3 illustrates efficiency of a Doherty amplifier operating at different frequencies;

FIG. 4 illustrates a dual Doherty amplifier transmitter according to one embodiment;

FIG. 5 illustrates an alternative dual Doherty amplifier transmitter according to one embodiment;

FIG. 6A and B illustrate performance of the dual Doherty amplifiers of FIG. 4 and FIG. 5; and

FIG. 7 illustrated a dual Doherty power amplifier process.

### DETAILED DESCRIPTION

The following description, given by way of example only, is described in order to provide a more precise understanding of one or more of the embodiments. In the figures, like reference numerals are used to identify like parts throughout the figures.

Disclosed is a dual Doherty amplifier transmitter for use with millimetre wavelength signals that may be suitable for high frequency signals, such as those used for the 5G NR frequency standard. The dual Doherty amplifier transmitter may operate for frequencies anywhere from many MHz to hundreds of GHz. Some example ranges of operation include operating in a range between 0.5 to 6, 9 to 15, 20 to 100, 1 to 100, 1 to 200, 1 to 300, or 1 to 400 GHz. The transmitter includes a plurality of driver amplifiers, each of the plurality of driver amplifiers receiving an input signal mixed with a carrier signal. The transmitter also includes a plurality of Doherty power amplifiers configured in parallel and configured to operate separately, each of the plurality of Doherty power amplifiers having an input with a different phase, wherein each of the plurality of Doherty power amplifiers is paired with a corresponding driver amplifier from the plurality of driver amplifiers. The dual Doherty power amplifier may be used a mobile device, such as a mobile telephone.

### Doherty Power Amplifier

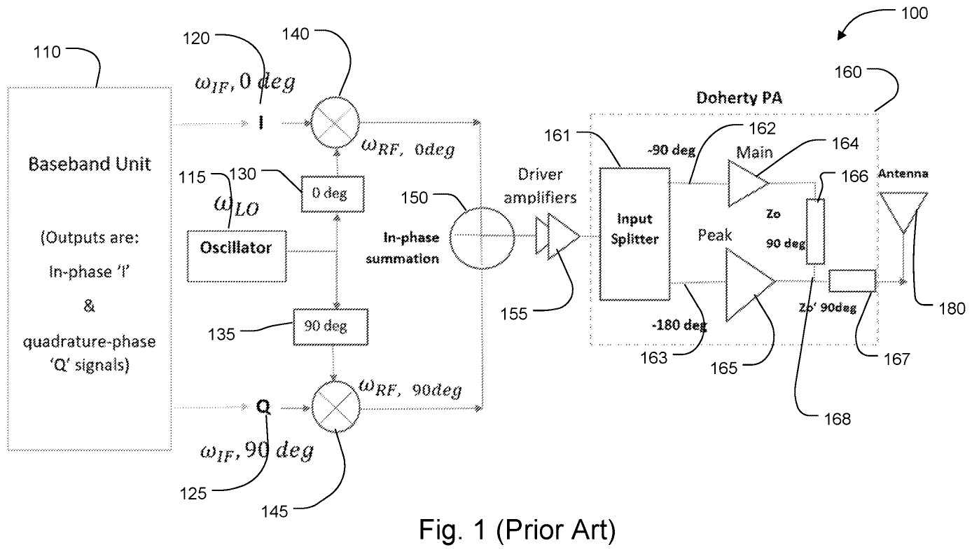

FIG. 1 is an example of a radio transmitter which contains a Doherty power amplifier. The radio frequency transmitter 100 has a baseband unit 110 that receives a signal. The baseband unit 110 generates two outputs, an in-phase signal 120 and a quadrature phase signal 125 which has a 90 degree phase difference to the in-phase signal 120. An oscillator 115 generates a carrier signal that is combined with each of the in-phase signal 120 and the quadrature phase signal 125. The signal from the oscillator 115 passes through a phase shifter 130 which applies a zero degree phase shift before combining the carrier signal from the oscillator 115 with the in-phase signal 120 at a frequency mixer 140. A similar process occurs for the quadrature phase signal 125 where the carrier signal of the oscillator 115 passed through a quadrature phase shifter 135 that shifts the phase of the carrier signal by 90 degrees, to match the phase of the quadrature phase signal 125. The phase shifted carrier signal is combined with the quadrature phase signal 125 at a quadrature frequency mixer 145.

The output of the frequency mixer 140 and the quadrature frequency mixer 145 are combined at an in-phase summation 150 before being amplified by a driver amplifier 155. Output from the driver amplifier 155 is sent to a Doherty amplifier 160 which receives the output of the driver amplifier 155 at an input splitter 161.

The Doherty amplifier 160 has two amplifiers, a main amplifier 164 and a peak or auxiliary amplifier 165. The Doherty amplifier 160 relies on load modulation where changing the loading conditions of the main amplifier 164 by fast switching of the peak amplifier 165 allows the Doherty amplifier 160 to maintain high efficiency at both high and low powers, i.e., over a wide amplitude range of the signal.

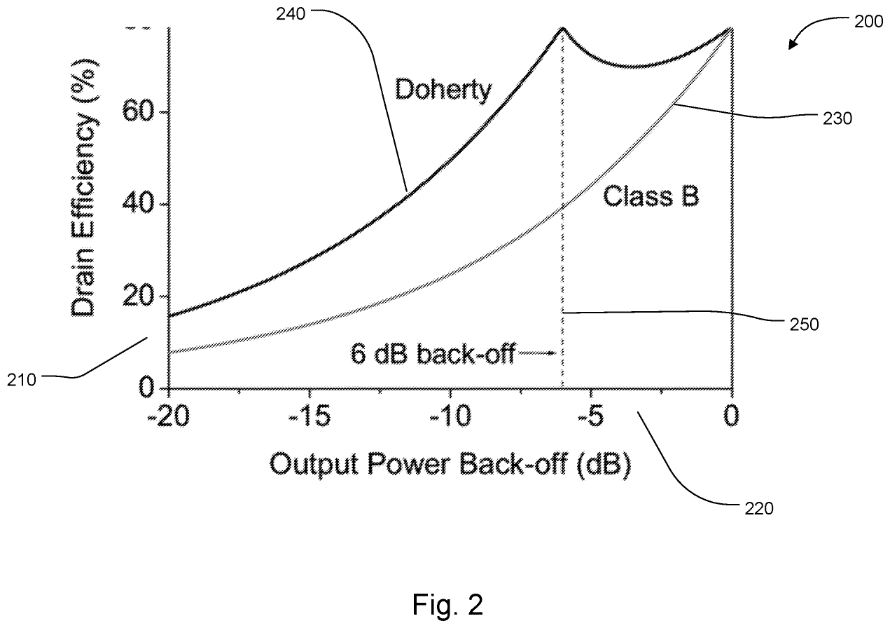

Load modulation of a power amplifier changes output power of the power amplifier, gain and efficiency characteristic. If the load at the output of the power amplifier is kept fixed or constant, the efficiency rolls off as the instantaneous signal level drops for signals with variable amplitude or a high peak-to-average ratio. This may be seen in FIG. 2 which will be explained below.

The Doherty amplifier 160 achieves high efficiency in ‘power back-off’ by load modulating or changing the load experienced by the main amplifier 164 as the peak amplifier 165 turns on and off. The peak amplifier 165 is usually biased closer to threshold voltage of the transistor, referred to as a class-C bias, to ensure the peak amplifier 165 is off during back-off or low-level signal conditions, while the main amplifier 164 is biased such that the main amplifier 164 is always on, referred to as class AB or B. The efficiency enhancement in the Doherty amplifier 160 at back-off power-level, which corresponds to the average power of a variable amplitude signal can be seen below in FIG. 2.

In the Doherty amplifier 160, the in-phase signal 162 and the quadrature signal 163 are connected to the output ports of the input splitter 161, which may be a 3 or 4-port passive radio frequency network. The input of the input splitter 161 is excited by an OFDM (orthogonal frequency-division multiplexing) signal. A phase difference between an in-phase signal 162 and a quadrature signal 163 of the input splitter 161 should be 90 degrees to ensure the in-phase signal 162 and the quadrature signal 163 add in phase at a combining node 168 of the radio frequency transmitter 100, which is the junction of 90-degree, or quarter-wavelength, impedance transformers of an impedance inverter 166 and impedance inverter 167 before being sent to an antenna 180.

The input splitter 161 divides input power between a main amplifier 164 and a peak amplifier 165, either in equal or unequal proportions, depending on the power level at which the modulation of the main amplifier 164 load should begin, i.e., when the peak amplifier 165 should turn on. The amplitude split as well as the phase differences the signals experience at the input is important in achieving load modulation at output of the main amplifier 164 and the peak amplifier 165. While load modulation of the main amplifier 164 is necessary and desirable, load modulation of the peak amplifier 165 is not desired. Nonetheless, both the main amplifier 164 and the peak amplifier 165 load modulate each other over the variation of the signal amplitude.

Output of the main amplifier 164 and the peak amplifier 165 are connected to each other by an output combiner, sometimes referred to as Doherty combiner, which consists of the impedance inverter 166, impedance inverter 167 and the combining node 168. Impedance inverters are implemented as quarter-wavelength (90 degree) transmission lines with a characteristic impedance Zo. The output of the main amplifier 164 connects to the impedance inverter 166, where the impedance inverter 166 connects to the peak amplifier 165 as shown. The Doherty combiner does not have to be an impedance implemented as impedance inverters, as shown with the impedance inverter 166 and the impedance inverter 167. The Doherty combiner can also be a 3-port radio-frequency network which provides appropriate impedances at the main amplifier 164 and the peak amplifier 165 for a given power level, while ensuring a phase difference between input ports connected to the main amplifier 164 and the peak amplifier 165 is 90-degrees.

At low power levels, that is for signals below a certain threshold, the peak amplifier 165 is off. When the peak amplifier 165 is off, the main amplifier 164 experiences loading condition that leads to lower power and high efficiency, as the main amplifier 164 operates close to saturation for that load condition.

When the signal to the Doherty amplifier 160 exceeds a threshold level, the peak amplifier 165 turns on, thereby changing the load conditions at the node that connects the impedance inverter to the Doherty power amplifier output load. Due to changing impedance on one side of the impedance inverter 166, the impedance seen by the main amplifier 164 transforms to a value that results in higher power while also maintain high efficiency at the load condition. At maximum output power of the Doherty power amplifier, the output power from the main amplifier 164 combines with that of the peak amplifier 165 to provide a high output power relative to the state when the peak amplifier 165 is off. The ability to change power level while maintaining high efficiency results in a high efficiency for a variable amplitude signal with high peak-to-average ratio, as will be described in relation to FIG. 2.

Alternative Doherty power amplifiers have also been proposed. For instance, a 3-way Doherty uses an extra peak amplifier and an extra impedance inverter on top of what was described in relation to the 2-way Doherty amplifier 160 of FIG. 1. The 3-way Doherty amplifier provides extended back-off efficiency that is not possible with a 2-way Doherty. The 3-way Doherty power amplifier architecture also comes with greater complexity and lower gain (amplification). The same is true for a 4-way Doherty power amplifier or a more generalised n-way Doherty power amplifier, both of which are superior to the 2-way Doherty for back-off efficiency but with a trade-off of lower gain and increased complexity. Reduced gain is not a significant issue at sub-6 GHZ frequencies where the amplifier gain is high but becomes a serious issue at millimetre wavelength frequencies, particularly in peak amplifiers.

FIG. 2 shows an efficiency graph 200 that compares a class B amplifier 230 to a Doherty amplifier 240 by comparing efficiency 210 to back-off power 220. As described above, in relation to the Doherty amplifier 160, the use of the main amplifier 164 and the peak amplifier 165 results in high efficiency for a signal with a high peak-to-average ratio compared to the class B amplifier 230. The efficiency graph 200 also shows that the Doherty amplifier 240 has an efficiency peak at 6 dB back-off 250.

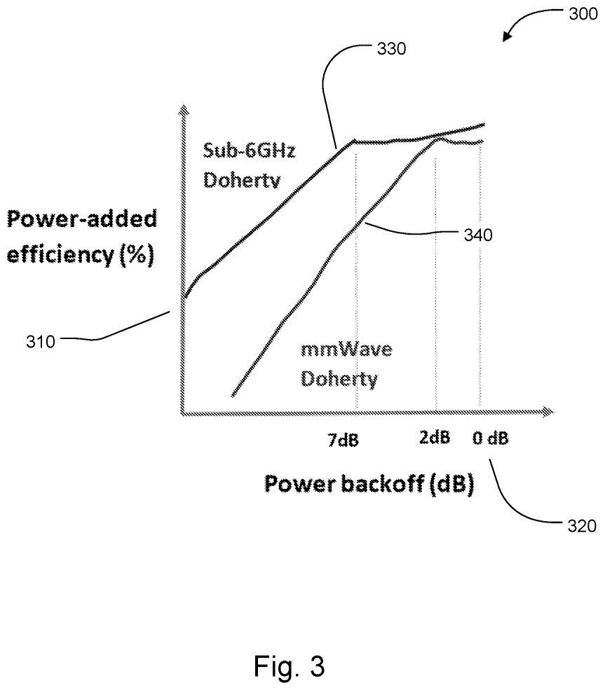

FIG. 3 shows a back-off efficiency graph 300 for a Doherty amplifier. The back-off efficiency graph 300 illustrates the back-off efficiency performance of a millimetre wavelength Doherty amplifier which shows significant degradation in comparison to a low-frequency Doherty power amplifier operating at less than 6 GHz. The back-off efficiency graph 300 has a y-axis of efficiency 310 and an x-axis of back-off power 320. Shown are curves for a sub-6 GHz Doherty amplifier 330 and a millimetre wavelength Doherty amplifier 340. As seen in the back-off efficiency graph 300, the efficiency of the millimetre wavelength Doherty amplifier 340 is generally lower than the sub-6 GHZ Doherty amplifier 330.

### Dual Doherty Power Amplifier

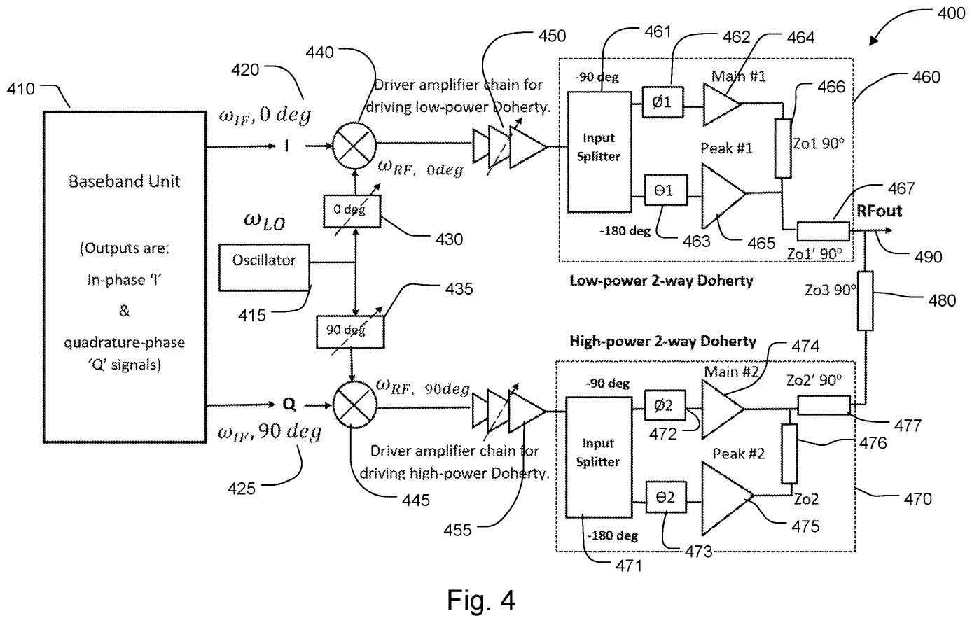

FIG. 4 shows a dual Doherty amplifier transmitter 400 that may overcome limitations of semiconductor technology at millimetre wavelength frequencies and ameliorate the consequent impact on efficiency. The dual Doherty amplifier transmitter 400 differs in a number of ways to the radio frequency transmitter 100, described above, including having a low power 2-way Doherty amplifier and a high power 2-way Doherty amplifier. The use of dual 2-way Doherty amplifiers in the transmitter may provide improved operational efficiency compared to the radio frequency transmitter 100, especially when operating at millimetre wavelength frequencies. Further, the dual Doherty amplifier transmitter 400 keeps an in-phase and quadrature phase line separate, with the in-phase line, also referred to as a quadrature phase transmission path and an in-phase transmission path, being input to one of the Doherty amplifiers and the quadrature phase line being input to the other Doherty power amplifier. The in-phase and quadrature lines are combined after the Doherty power amplifiers.

The dual Doherty amplifier transmitter 400 has a baseband unit 410 that operates in a similar manner to the baseband unit 110. Output from the baseband unit 410 is an in-phase signal 420 and a quadrature phase signal 425, having a 90 degree phase difference. In other words the signals 420 and 425 are orthogonal to each other. Output from an oscillator 415, which acts as a carrier signal, is split to be phase adjusted with the output feeding to a phase shifter 430 with a zero degree phase shift, or no phase shift. The output from the phase shifter 430 is fed to a frequency mixer 440 where the output of the oscillator 415 is mixed with the in-phase signal 420. Both the in-phase signal 420 and the phase shifter 430 have the same frequency shift of zero degrees. The output of the oscillator 415 is also fed to a quadrature phase shifter 435 where the carrier signal, the output of the oscillator 415, is phase adjusted and undergoes a 90 degree phase shift. The phase shifted output of the oscillator 415 is then mixed with the quadrature phase signal 425 at a quadrature frequency mixer 445. The output of the quadrature phase shifter 435 and the quadrature phase signal 425 have a matching phase shift of 90 degrees.

The output of the frequency mixer 440 is sent as in input signal to a LP (low power) driver amplifier chain 450 where the signal is amplified before input to a low power Doherty amplifier 460. Similarly, the output of the quadrature frequency mixer 445 is sent as an input signal to a HP (high power) driver amplifier chain 455 where the signal is amplified before input to a high power Doherty amplifier 470. Each of the driver amplifiers and the Doherty power amplifiers operate on one of the transmission paths with each of the Doherty power amplifiers being paired with a corresponding driver amplifier. That is, a first driver amplifier, such as the LP driver amplifier chain 450, is paired with a first Doherty power amplifier, the low power Doherty amplifier 460, on a first transmission path. Similarly, a second driver amplifier, the LP driver amplifier chain 450, is paired with a second Doherty power amplifier, high power Doherty amplifier 470, on a second transmission path.

The low power Doherty amplifier 460 has a LP input splitter 461 that sends a signal to a LP in-phase phase compensator 462 and a LP quadrature phase compensator 463. The LP in-phase phase compensator 462 connects to a LP main amplifier 464. After the LP main amplifier 464 the phase is corrected by an impedance inverter 466 before combination with the amplified signal of the LP quadrature phase compensator 463. The LP quadrature phase compensator 463 connects to a LP peak amplifier 465 before being combined with the phase corrected signal from the impedance inverter 466. The impedance inverter 466 ensures load modulation of the LP main amplifier 464 within the low power Doherty amplifier 460 by the LP peak amplifier 465 present in the low power Doherty amplifier 460. The combined signal passes through an impedance inverter 467 before being output.

The high power Doherty amplifier 470 has a HP input splitter 471 that sends a signal to a HP in-phase phase compensator 472 and a HP quadrature phase compensator 473. The HP in-phase phase compensator 472 connects to a HP main amplifier 474. The HP quadrature phase compensator 473 connects to a HP peak amplifier 475 before connecting to an impedance inverter 476. The impedance inverter 476 ensures load modulation of the HP main amplifier 474 by the HP peak amplifier 475. The output of the impedance inverter 476 is combined with the output of the HP main amplifier 474 before passing through another impedance inverter 477. The output of the high power Doherty amplifier 470 passes through a LP-HP output combining network 480 before being combined with the output of the low power Doherty amplifier 460. One difference between the low power Doherty amplifier 460 and the high power Doherty amplifier 470 is that the impedance inverter 466 is applied to the output of the LP main amplifier 464 while the impedance inverter 476 is applied to the output of the HP peak amplifier 475 in the high power Doherty amplifier 470. The phase shifter for the high power Doherty amplifier 470 is applied to the HP peak amplifier 475, instead of the HP main amplifier 474 as the high power Doherty amplifier 470 is operating on the quadrature phase line, instead of the in-phase line.

The phase shifters of the low power Doherty amplifier 460 and the high power Doherty amplifier 470 serve the purpose of modifying signal phases so that the signals may be combined with the correct phase.

The dual Doherty amplifier transmitter 400 employs two separate Doherty power amplifiers, each with a different output power capability. The pair of Doherty power amplifiers are electrically connected. The low power Doherty amplifier 460 operates as a Doherty power amplifier with lower output power and has a limited back-off efficiency at millimetre wavelength frequencies, such as 28 GHz. The second Doherty amplifier, denoted as the high power Doherty amplifier 470, has a higher output power and also has limited back-off efficiency at millimetre wavelength frequencies. Both the low power Doherty amplifier 460 and the high power Doherty amplifier 470 are combined with a LP-HP output combining network 480, which may be a 90-degree impedance transformer located between the low power Doherty amplifier 460 and the high power Doherty amplifier 470, and a combining node output 490. The LP-HP output combining network 480 may be considered to be an output phase shifter. The arrangement of the dual Doherty amplifier transmitter 400 provides a back-off efficiency improvement for orthogonal frequency-division multiplexing signals. Appropriate phase relationships between the input signals exciting the low power Doherty amplifier 460 and the high power Doherty amplifier 470 is important to achieve higher back-off efficiency when compared to a transmitter such as the radio frequency transmitter 100. A 90-degree phase difference is used at inputs of the low power Doherty amplifier 460 and the high power Doherty amplifier 470 to allow the signals to be combined in phase at the output 490. This may be achieved by directly feeding the up-converted RF signals generated from the in-phase signal 420 and the quadrature phase signal 425 as the inputs of to the low power Doherty amplifier 460 and the high power Doherty amplifier 470.

The presence of the LP-HP output combining network 480 as a 90-deg impedance transformer between the output 490 and the high power Doherty amplifier 470 performs a two-step function. Firstly, the LP-HP output combining network 480 ensures that the low power Doherty amplifier 460 is load-modulated by the high power Doherty amplifier 470 at higher powers. Secondly, the LP-HP output combining network 480 also ensures signals arriving from the low power Doherty amplifier 460 and the high power Doherty amplifier 470 at output 490 add constructively over a range of input signal power levels. In this manner, a combination of the low power Doherty amplifier 460 and the high power Doherty amplifier 470 of different output powers constructively combines the signal while also ensuring efficiency of each Doherty amplifier is maintained in back-off through load-modulation.

As stated above, the dual Doherty amplifier transmitter 400 differs to the radio frequency transmitter 100 in having two Doherty amplifiers compared to the single Doherty amplifier of the radio frequency transmitter 100. Another difference is how the in-phase signal and the quadrature phase signal are processed. In the radio frequency transmitter 100 the in-phase signal 120 and the quadrature phase signal 125 have a carrier signal added before being combined at the in-phase summation 150 and sent to the Doherty amplifier 160. However, the dual Doherty amplifier transmitter 400 does not combine the in-phase signal 420 and the quadrature phase signal 425 until after the signals have been amplified. That is, the in-phase signal 420 is amplified by the low power Doherty amplifier 460 before the in-phase signal 420 is combined with the quadrature phase signal 425 that is amplified by the high power Doherty amplifier 470. The in-phase signal 420 and the quadrature phase signal 425 are both amplified before combining.

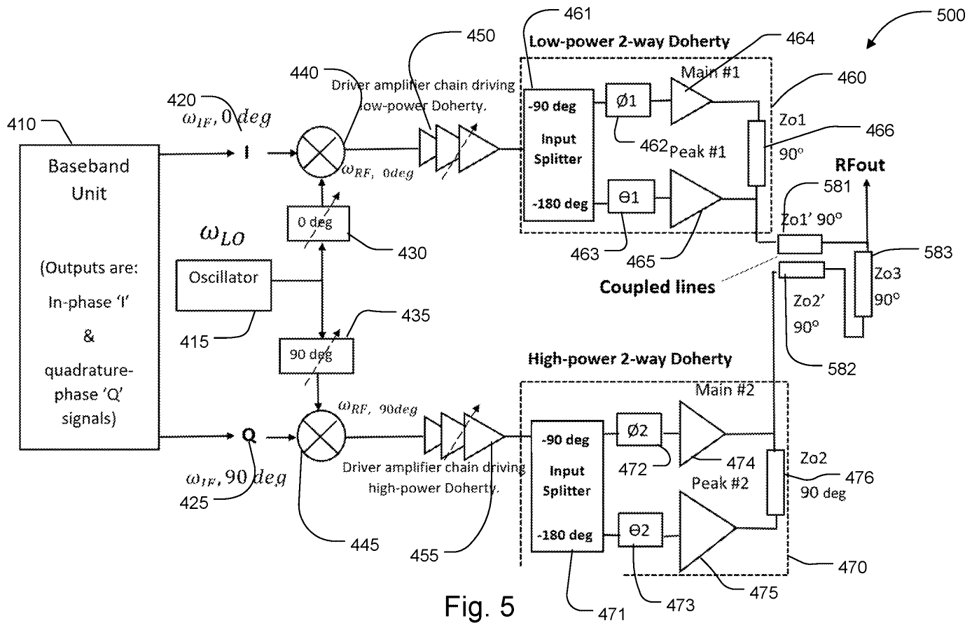

FIG. 5 shows an alternative dual Doherty amplifier transmitter 500. The alternative dual Doherty amplifier transmitter 500 has a number of similar components and features with the dual Doherty amplifier transmitter 400 described above. The baseband unit 410 generates the in-phase signal 420 and the quadrature phase signal 425 that are combined with a carrier signal from the oscillator 415 before being processed by the low power Doherty amplifier 460 and the high power Doherty amplifier 470 respectively.

The alternative dual Doherty amplifier transmitter 500 differs from the dual Doherty amplifier transmitter 400 in terms of how the output network is constructed. In a two away Doherty amplifier, such as the Doherty amplifier 160 described above, there is an impedance inverter 167, implemented as an impedance inverter or 90-deg impedance transformer, between the combining node 168 and the antenna 180. The impedance inverter 167 typically transforms impedance at the combining node 168 to the antenna 180. When compared to the dual Doherty amplifier transmitter 400 the corresponding impedance inverter 467 and the impedance inverter 477 are replaced by a LP-HP phase shifter 581 and a LP-HP phase shifter 582, which are a set of 90-degree coupled lines that may be impedance inverters. The LP-HP phase shifter 581 and the LP-HP phase shifter 582 operate as coupled phase shifters located on the output of the Doherty power amplifier. That is the LP-HP phase shifter 581 and LP-HP phase shifter 582 are located after the Doherty power amplifiers and may be considered to be output phase shifters. The coupled phase shifters are positioned close enough, in terms of physical proximity, that energy can pass between the LP-HP phase shifter 581 and the LP-HP phase shifter 582. The advantage of having coupled lines is that the overall impedance of the lines can be set by the coupling factor of the coupled lines, which is determined by the physical proximity of the lines. Furthermore, the use of coupled lines instead of the discrete set of 90-degree lines of the impedance inverter 467 and the impedance inverter 477 has the advantage of achieving a more compact circuit size. After the LP-HP phase shifter 582 is a LP-HP phase shifter 583 before the in-phase and quadrature phase lines are combined for output.

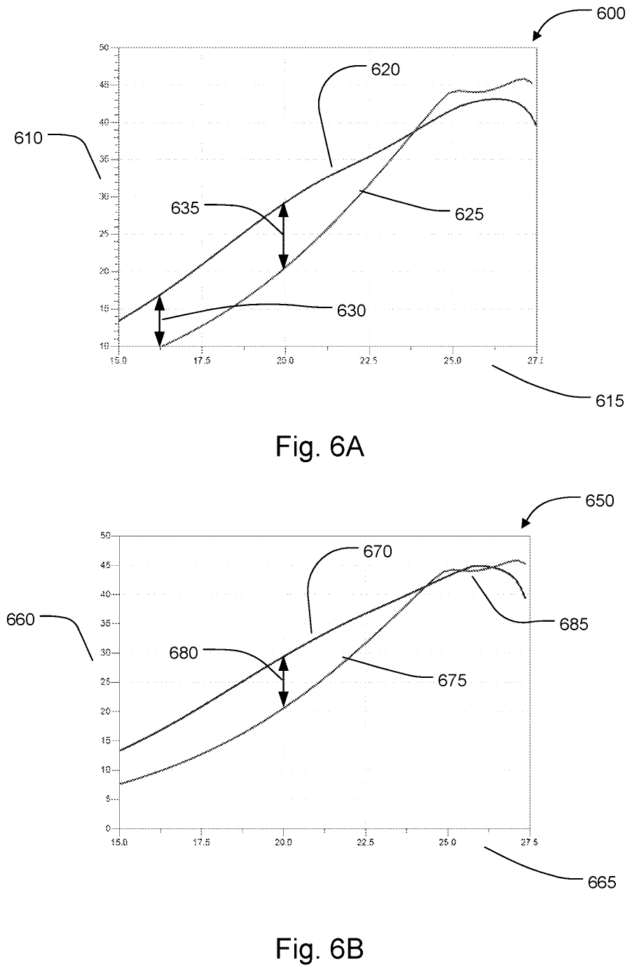

FIG. 6A shows a performance graph 600 comparing a dual Doherty amplifier 620, such as the dual Doherty amplifier transmitter 400 described above, to a two way Doherty amplifier 625, such as the radio frequency transmitter 100 described above. The performance graph 600 shows a y-axis of efficiency 610 and an x-axis of power output 615.

The efficiency of the dual Doherty amplifier 620 is approximately ten percent higher than the two way Doherty amplifier 625 as indicated by a higher power efficiency gap 635. At a lower power efficiency gap 630 the efficiency of the dual Doherty amplifier 620 is approximately seven percent greater than the two way Doherty amplifier 625

FIG. 6B shows a performance graph 650 comparing an alternative dual Doherty amplifier 670, such as the alternative dual Doherty amplifier transmitter 500, and a two way Doherty amplifier 675, such as the radio frequency transmitter 100. The performance graph 650 has a y-axis of efficiency 660 and an x-axis of power output 665. The efficiency of the alternative dual Doherty amplifier 670 is generally greater than the efficiency of the two way Doherty amplifier 675. At a power efficiency gap 680 the alternative dual Doherty amplifier 670 is approximately ten percent more efficient than the two way Doherty amplifier 675. One advantage of the alternative dual Doherty amplifier 670, compared to the dual Doherty amplifier 620 of the performance graph 600, is a higher efficiency at higher powers, as can be seen at a high power region 685.

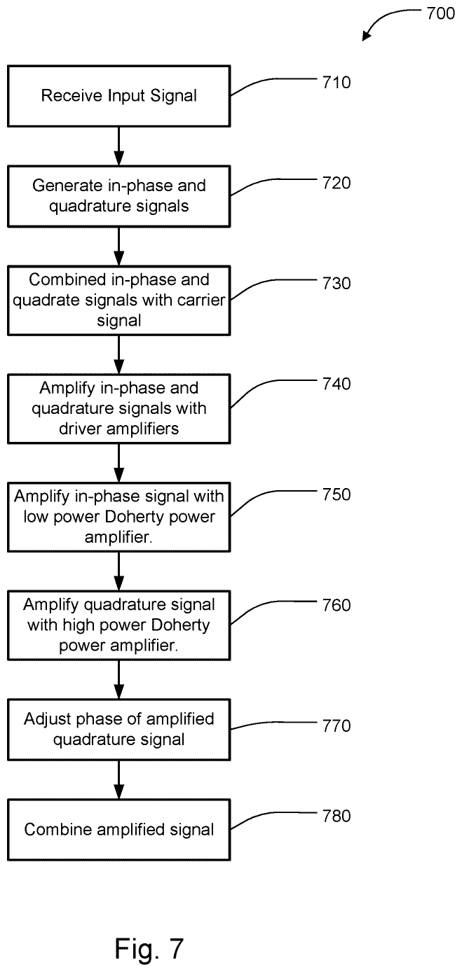

A dual Doherty power amplifier process 700 will now be described in relation to FIG. 7. The dual Doherty power amplifier process 700 may be performed by a dual Doherty power amplifier, such as the dual Doherty amplifier transmitter 400 or the alternative dual Doherty amplifier transmitter 500. The dual Doherty power amplifier process 700 starts with a receive input signal 710 where the signal to be transmitted is received. Next, a generate phase signals 720 generates an in-phase signal and a quadrature phase signal from the input signal. The receive input signal 710 and the generate phase signal 720 may be performed by the baseband unit 410.

At add carrier signal 730 the in-phase signal is combined with a carrier signal, as performed by the oscillator 415, the phase shifter 430 and the frequency mixer 440, while the quadrature phase signal is combined with the carrier signal, such as the performed by the oscillator 415, quadrature phase shifter 435 and the quadrature frequency mixer 445. The output of the add carrier signal 730 is a combined in-phase signal and a combined quadrature signal.

At amplify with driver amplifiers 740, the combined in-phase signal and the combined quadrature signal are amplified by driver amplifiers, such as the LP driver amplifier chain 450 or the HP driver amplifier chain 455. For the in-phase signal, the output from the driver amplifiers is sent to a low power Doherty power amplifier, such as the low power Doherty amplifier 460 or the low power Doherty amplifier 560, to generate an amplified in-phase signal at apply low power Doherty power amplifier 750. The output from the driver amplifier for the quadrature phase signal is sent to a high power Doherty power amplifier, such as the high power Doherty amplifier 470 or the high power Doherty amplifier 570, to generate an amplified quadrature signal at apply high power Doherty power amplifier 760.

At adjust output signal phase 770, one, or both, of the amplified in-phase signal and the amplified quadrature signal have their phase adjusted by an output phase shifter so that the signals can be combined. Typically the quadrature phase signal is adjusted, as described above for the LP-HP output combining network 480 for the dual Doherty amplifier transmitter 400 or by the LP-HP phase shifter 583 for the alternative dual Doherty amplifier transmitter 500. The output of the adjust output signal phase 770 is the amplified in-phase signal and the amplified quadrature phase signal are now in-phase and combined at combine signals 780 before being transmitted.

### Dual Doherty Amplifier Features

Aspects of a dual Doherty amplifier transmitter, such as the dual Doherty amplifier transmitter 400 and the alternative dual Doherty amplifier transmitter 500 will now be described. The aspects described below may be used to achieve high power and efficiency increases over existing transmitter designs over a wide range of input powers.

One aspect of the dual Doherty amplifier is the 90-degree phase difference between the low power Doherty amplifier 460 and the high power Doherty amplifier 470. The 90-degree phase difference is performed by direct feeding of up-converted forms of the in-phase signal 420 and the quadrature phase signal 425 from the output of the frequency mixer 440 and the quadrature frequency mixer 445 into the low power Doherty amplifier 460 and the high power Doherty amplifier 470 respectively. The arrangement requires an appropriate 0 and 90-degree phase shift applied to the output of the oscillator 415 by the phase shifter 430 and the quadrature phase shifter 435.

The embodiments describe that a 90-degree phase difference between the inputs of the low power Doherty amplifier 460 and the high power Doherty amplifier 470 should be preserved. While this is true for an ideal case where the amplified modulated signal produced at the output of the dual Doherty amplifier transmitter 400 or the alternative dual Doherty amplifier transmitter 500 depends on ensuring a 90-degree phase difference to be preserved as the constituent signals are combined at the output. However, this is based on an assumption that signals amplified by both the low power Doherty amplifier 460 and the high power Doherty amplifier 470 do not experience any distortion and do not suffer from phase distortion, which is not the case in practise. Furthermore, the phase shift experienced by the signal at a certain power level also impacts load modulation experienced by the output of the Doherty power amplifier. For this reason, incorrect phase relationships between signals from the low power Doherty amplifier 460 and the high power Doherty amplifier 470 may mean the pre-amplified signals, such as the output of the frequency mixer 440 and the quadrature frequency mixer 445, may need a phase angle difference other than 90 degrees, although the phase angle difference will be substantially 90 degrees. The different phase angles may compensate for the impact of phase distortion experienced by the signals being amplified by the Doherty power amplifiers.

To enable the different phase angles, other than 90 degrees, the phase shifter 430 and the quadrature phase shifter 435 may have variable phase. That is, the phase shifter 430 and the quadrature phase shifter 435 may be implemented as variable phase shifters. Varying the phase of the phase shifter 430 and the quadrature phase shifter 435 may be considered a form of pre-distortion of phase to compensate for phase distortion created by the Doherty power amplifiers. The phase shifter 430 and the LP driver amplifier chain 450 apply pre-distortion to the up-converted RF signal from the in-phase signal 420 and the quadrature phase shifter 435 and the driver amplifier 455 apply pre-distortion to the up-converted RF signal from the quadrature phase signal 425. Alternatively, the phase shifter 430 and the LP driver amplifier chain 450 can be considered to apply pre-distortion to the up-converted RF signal after the frequency mixer 440. Similarly, the quadrature phase shifter 435 and the HP driver amplifier chain 455 apply pre-distortion to the up-converted RF signal from the quadrature frequency mixer 445. As such, this approach represents a form of a linearisation technique, which preserves signal characteristics in the event of power amplifier distortion.

The low power Doherty amplifier 460 and the high power Doherty amplifier 470 may introduce AM-AM distortion in the signal, which is characterized by amplitude modulation at the input, resulting in amplitude modulation at the output of the low power Doherty amplifier 460 or the high power Doherty amplifier 470. A second type of distortion, AM-PM distortion, may occur where amplitude modulation at the input of the low power Doherty amplifier 460 or high power Doherty amplifier 470 creates phase modulation at the output. In other words, the low power Doherty amplifier 460 and the high power Doherty amplifier 470 each distort signals passing through them. The distortion can be characterized as either AM-AM distortion and/or AM-PM distortion. The AM-AM distortion contribution is in the amplitude domain and the AM-PM distortion is in the phase domain, both of which are a result of changing input signal amplitude. By creating pre-distortion, or a correctional phase shift, the dual Doherty amplifier transmitter 400 applies linearization to the signal passing through the dual Doherty amplifier transmitter 400. The amount of pre-distortion applied to the up-converted RF signal is adjusted using a variable gain in either the LP driver amplifier chain 450 or the HP driver amplifier chain 455 for the in-phase phase transmission path and the quadrature transmission path respectively. The pre-distortion of the LP driver amplifier chain 450 or the HP driver amplifier chain 455 may reduce the AM-AM distortion. The amount of pre-distortion may also be adjusted using the variable phase of the phase shifter 430 or the quadrature phase shifter 435 to reduce the AM-PM distortion.

An appropriate or correct power split between the in-phase line and the quadrature phase line, between the frequency mixer 440 output and the low power Doherty amplifier 460 input as well as the quadrature frequency mixer 445 output and the high power Doherty amplifier 470 input, is important for ensuring that only the low power Doherty amplifier 460 is activated at low powers and the high power Doherty amplifier 470 is in an off state. Beyond a certain input power level, the high power Doherty amplifier 470 turn on and contributes to the overall output power of the dual Doherty amplifier transmitter 400 or the alternative dual Doherty amplifier transmitter 500. The low power Doherty amplifier 460 or the low power Doherty amplifier 560 may be considered to be a first Doherty power amplifier that is active for all power ranges and the high power Doherty amplifier 470 or the high power Doherty amplifier 570 may be considered to be a second Doherty power amplifier that is inactive for lower power ranges and active for higher power ranges. The low power Doherty amplifier 460 or the low power Doherty amplifier 560 may be considered to be on a first transmission path and the high power Doherty amplifier 470 or the high power Doherty amplifier 570 may be considered to be on a second transmission path. In addition, the activation of the high power Doherty amplifier 470 changes the loading conditions of the low power Doherty amplifier 460 so that high efficiency may be maintained at high powers. The low power Doherty amplifier 460 and the high power Doherty amplifier 470 are configured to operate separately. The low power Doherty amplifier 460 is activated during operation of the transmitter while the high power Doherty amplifier 470 is activated at high power levels. The high power Doherty amplifier 470 may be considered to be selectively operated as the high power Doherty amplifier 470 operates when the dual Doherty power amplifier is in a predetermined state. At low power levels, that is for signals below a certain threshold, the high power Doherty amplifier 470 is off. The high power Doherty amplifier 470 is activated based on DC bias conditions and a ratio of an amplitude split between the transmission paths of the low power Doherty amplifier 460 and the high power Doherty amplifier 470.

The LP driver amplifier chain 450 and the HP driver amplifier chain 455 may have variable/adjustable gain, as indicated by a diagonal arrow across each of the driver amplifier chains. The variable gain may allow the amplitude split between the in-phase line and the quadrature line to be optimised to ensure that the power split to the low power Doherty amplifier 460 and the high power Doherty amplifier 470 is optimal.

A 90-degree phase compensation, such as the LP-HP output combining network 480 of the dual Doherty amplifier transmitter 400 and the LP-HP phase shifter 583 of the alternative dual Doherty amplifier transmitter 500 is used at an output of the dual Doherty amplifier transmitter 400 and the alternative dual Doherty amplifier transmitter 500. The 90-degree phase compensation is used so that output from the low power Doherty amplifier 460 and the high power Doherty amplifier 470 add together in phase and operates as an output phase shifter. The 90-degree phase compensation also creates load-modulation between the low power Doherty amplifier 460 and the high power Doherty amplifier 470 for efficiency enhancement over a range of input powers, which is activated a predetermined input power level. The output phase shifter ensures that the low power Doherty power amplifier is load-modulated by the high power Doherty power at higher powers of operation.

The use of a pair of Doherty power amplifiers alone may not be enough to get wide-backoff operation. The use of the LP in-phase phase compensator 462 and the LP quadrature phase compensator 463 may correct or improve phases or phase angles between the signals at the output of the low power Doherty amplifier 460. Similarly for the HP in-phase phase compensator 472 and the HP quadrature phase compensator 473 for the high power Doherty amplifier 470. The result is that the low power Doherty amplifier 460 and the high power Doherty amplifier 470 in a transmitter may see substantially optimal loading conditions at various power levels. The substantially optimal loading conditions allows a wide-backoff efficiency characteristic by the combination of the two Doherty power amplifiers and controlling their activity.

### Variations

Values for a number of elements in the dual Doherty amplifier transmitter 400 and the alternative dual Doherty amplifier transmitter 500 may be changed depending on the overall electrical design, selection of other elements and parasitic elements in the transistor devices used within the individual Doherty power amplifiers. The elements may include the phase shifter 430, quadrature phase shifter 435, LP driver amplifier chain 450, HP driver amplifier chain 455, LP in-phase phase compensator 462, LP quadrature phase compensator 463, HP in-phase phase compensator 472, HP quadrature phase compensator 473, impedance inverter 466, impedance inverter 476, impedance inverter 467, impedance inverter 477, LP-HP output combining network 480, LP-HP phase shifter 581, LP-HP phase shifter 582 and LP-HP phase shifter 583.

Elements such as the phase shifter 430 and quadrature phase shifter 435 of the dual Doherty amplifier transmitter 400 and the alternative dual Doherty amplifier transmitter 500 may be used to ensure correct phase relationships exist between input and output signal of the low power Doherty amplifier 460 and the high power Doherty amplifier 470. Since, size of transistors, bias conditions, and other matching components all impact on the phase relationship of the signals, the LP in-phase phase compensator 462, LP quadrature phase compensator 463, HP in-phase phase compensator 472 and HP quadrature phase compensator 473 may not be needed and when used may be optimized to ensure optimal performance of the low power Doherty amplifier 460 and the x870.

As described, the amplifiers of the dual Doherty amplifier transmitter 400 and the alternative dual Doherty amplifier transmitter 500 will activate in the order of the LP main amplifier 464, LP peak amplifier 465, HP main amplifier 474 then HP peak amplifier 475. However, alternative activation orders may also be possible. For example, the amplifiers may be activated in the order LP main amplifier 464, HP main amplifier 474, LP peak amplifier 465 and HP peak amplifier 475.

While the dual Doherty amplifier transmitter 400 and the alternative dual Doherty amplifier transmitter 500 are shown with two Doherty power amplifiers, additional Doherty power amplifiers may be used in the transmitter.

### Advantages and Interpretations

While previous implementations of Doherty amplifiers are limited to efficiency-enhancement for variable amplitude signals, such as quadrature amplitude modulation or orthogonal frequency-division multiplexing, at a power-amplifier level, the dual Doherty amplifier transmitter 400 and the alternative dual Doherty amplifier transmitter 500 may be considered a true transmitter-efficiency enhancement architecture. A typical transmitter based on a conventional Doherty power amplifier cannot deliver adequate back-off efficiency performance at millimetre wavelength frequencies as shown by two way Doherty amplifier 625 in FIG. 6A.

One advantage of the dual Doherty amplifier transmitter 400 and the alternative dual Doherty amplifier transmitter 500 is that, unlike the radio frequency transmitter 100, the outputs of the frequency mixer 440 and the quadrature frequency mixer 445, or the frequency mixer 540 and the quadrature frequency mixer 545, need not be combined. This may provide a number of benefits for overall performance of a transmitter. Since the output of the frequency mixer 440 and the quadrature frequency mixer 445 are upconverted signals based on the in-phase signal 420 and the quadrature phase signal 425 with 90-deg phase difference, the signals may be directly fed to the low power Doherty amplifier 460 and the high power Doherty amplifier 470, which require a 90-degree phase difference in addition to an appropriate power split. Feeding the up-converted in-phase signal 420 and the quadrature phase signal 425 eliminates the need for a lossy input splitter to appropriately divide the input power between the low power Doherty amplifier 460 and the high power Doherty amplifier 470, while also introducing a 90-degree phase difference. Removing the lossy input splitter also improves the overall gain of the transmitter and thereby the power-added efficiency. Thus, a redundancy present in a transmitter such as the radio frequency transmitter 100 is removed since there is no need to combine the mixer outputs and then split them again. The dual Doherty amplifier transmitter 400, or alternative dual Doherty amplifier transmitter 500, may make it easier to create a tuneable power split between the paths, by altering the gains of the LP driver amplifier chain 450 and the HP driver amplifier chain 455, or the LP driver amplifier chain 550 and the HP driver amplifier chain 555, by means of bias control. The resulting improvement in efficiency of around 10% is evident over a large back-off up to 12 dB in FIG. 6A and FIG. 6B.

The dual Doherty power amplifier may achieve a more energy efficient and lower distortion transmission and amplification at millimetre wavelengths compared to a Doherty power amplifier.

Throughout this specification and the claims which follow, unless the context requires otherwise, the word “comprise”, and variations such as “comprises” or “comprising”, will be understood to imply the inclusion of a stated integer or step or group of integers or steps but not the exclusion of any other integer or step or group of integers or steps.

1. A transmitter for transmitting radio frequency and millimetre wavelength signals, the transmitter comprising:
a first and a second transmission path, each transmission path having a signal with a different phase;
a first driver amplifier on the first transmission path and a second driver amplifier on the second transmission path, each of the first and second driver amplifiers receiving an input signal mixed with a carrier signal; and
a first Doherty power amplifier on the first transmission path and a second Doherty power amplifier on the second transmission path, each of the first and the second Doherty power amplifiers having an input with a different phase and being configured to operate separately,
wherein first driver amplifier is paired with the first Doherty power amplifier and the second driver amplifier is paired with the second Doherty power amplifier.

2. The transmitter according to claim 1, further comprising:
a first output impedance inverter for an output of the first Doherty power amplifier; and
a second output impedance inverter for an output of the second Doherty power amplifier, the first output impedance inverter and the second output impedance inverter being positioned to act as coupled impedance inverters.

3. The transmitter according to claim 1, wherein the second Doherty power amplifier is selectively operated based on DC bias conditions and an amplitude split ratio between the first and the second transmission paths.

4. The transmitter according to claim 3, wherein the first Doherty power amplifier is a low power Doherty power amplifier that is active for all power ranges and the second Doherty power amplifier is a high power Doherty power amplifier that is inactive for lower power ranges and active for higher power ranges.

5. The transmitter according to claim 3, wherein the phase difference between the input to the first Doherty power amplifier and the second Doherty power amplifier is substantially 90 degrees.

6. The transmitter according to claim 1, wherein at least one of the first and the second driver amplifiers has an adjustable gain.

7. The transmitter according to claim 6, wherein the adjustable gain of the at least one driver amplifier varies an amplitude split between the first and the second Doherty power amplifiers.

8. The transmitter according to claim 1, wherein the carrier signal is generated by an oscillator.

9. The transmitter according to claim 1, wherein the carrier signal is phase adjusted before being received as input to at least one of the first and the second Doherty power amplifiers.

10. The transmitter according to claim 9, wherein a phase of the carrier signal is adjusted using a phase shifter for each of a plurality of Doherty power amplifiers, the phase shifter and a driver amplifier selected from a set of the first driver amplifier and the second driver amplifier applying pre-distortion to the up-converted RF signal.

11. The transmitter according to claim 10, wherein an amount of pre-distortion applied to the up-converted RF signal is adjusted using a variable gain of the driver amplifier and a variable phase of the phase shifter.

12. The transmitter according to claim 1, wherein each of the first and the second Doherty power amplifiers has a phase compensator for a main amplifier and a phase compensator for a peak amplifier.

13. The transmitter according to claim 1, wherein the transmitter frequency is between 0.5 to 6 GHZ.

14. The transmitter according to claim 1, wherein the transmitter frequency is between 20 to 100 GHz.

15. The transmitter according to claim 1, wherein each of the first and second transmission paths have an adjustable phase.

16. The transmitter according to claim 4, further comprising an output phase shifter that ensures that the low power Doherty power amplifier is load-modulated by the high power Doherty power at higher powers of operation.

17. The transmitter according to claim 4, wherein the low power Doherty power amplifier amplifies an in-phase signal and the high power Doherty power amplifier amplifies a quadrature phase signal before the in-phase signal and the quadrature phase signal are combined.

18. A mobile device comprising the transmitter according to claim 1.

19. A method of transmitting radio frequency and millimetre wavelength signals, the method comprising:
generating an in-phase signal and a quadrature phase signal from an input signal;
combining the in-phase signal with a carrier signal to form a combined in-phase signal and the quadrature signal with a carrier signal to form a combined quadrature signal;
amplifying the combined in-phase signal with a low power Doherty power amplifier to generate an amplified in-phase signal;
amplifying the combined quadrature signal with a high power Doherty power amplifier to generate an amplified quadrature signal;
generating an output signal by combining the amplified in-phase signal and the amplified quadrature signal after adjusting a phase of at least one of the amplified in-phase signal and the amplified quadrature signal; and
transmitting the output signal.

20. The method according to claim 19, wherein each of the combined in-phase signal and the combined quadrature phase signal are amplified by a driver amplifier.
